(19) United States
(12) Patent Application Publication
(10) Pub. No.: US 2011/0018018 A1
(43) Pub. Date: Jan. 27, 2011

(54) SEMICONDUCTOR CHIP PACKAGE STRUCTURE FOR ACHIEVING ELECTRICAL CONNECTION WITHOUT USING WIRE-BONDING PROCESS AND METHOD FOR MAKING THE SAME

(75) Inventors: BILY WANG, HSINCHU CITY (TW); HUNG-CHOU YANG, HSINCHU COUNTY (TW); JENG-RU CHANG, HSINCHU COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: HARVATEK CORPORATION, HSINCHU CITY (TW)

(21) Appl. No.: 12/648,559

(22) Filed: Dec. 29, 2009

(30) Foreign Application Priority Data
Jul. 24, 2009 (TW) 98125003

(51) Int. Cl. H01L 33/48; H01L 33/44; H01L 33/62; H01L 31/02; H01L 23/48; H01L 21/78; H01L 31/18

(52) U.S. Cl. 257/98; 257/99; 257/433; 257/690; 438/113; 438/27; 438/28; 438/64; 257/E33.056; 257/E33.061; 257/E33.066; 257/E31.11; 257/E23.01; 257/E21.599

(57) ABSTRACT

A semiconductor chip package structure for achieving electrical connection without using wire-bonding process includes an insulative substrate unit, a package unit, a semiconductor chip, a first conductive unit, an insulative unit and a second conductive unit. The package unit is disposed on the insulative substrate unit to form a receiving groove. The semiconductor chip is received in the receiving groove. The semiconductor chip has a plurality of conductive pads. The first conductive unit has a plurality of first conductive layers formed on the package body, and one side of each first conductive layer is electrically connected to each conductive pad. The insulative unit has an insulative layer formed between the first conductive layers in order to insulate the first conductive layers from each other. The second conductive unit has a plurality of second conductive layers respectively formed on another sides of the first conductive layers.

### BACKGROUND OF THE INVENTION

1. Field of the Invention

The present invention relates to a semiconductor chip package structure and a method for making the same, in particular, to a semiconductor chip package structure for achieving electrical connection without using wire-bonding process and a method for making the same.

2. Description of the Related Art

Referring to FIG. 1, a known LED package structure is packaged via a wire-bonding process. The known LED package structure includes a substrate 1a, an LED (light emitting diode) 2a disposed on the substrate, two wires 3a, and a phosphor resin body 4a.

The LED 2a has a light-emitting surface 20a opposite to the substrate 1a. The LED 2a has a positive pole area 21a and a negative pole area 22a electrically connected to two corresponding positive and negative pole areas 11a, 12a of the substrate 1a via the two wires 3a respectively. Moreover, the LED 2a and the two wires 3a are covered with the phosphor resin body 4a for protecting the LED 2a.

However, the method of the prior art not only increases manufacture time and cost, but also leads to uncertainty about the occurrence of bad electrical connections in the LED package structure of the prior art resulting from the wire-bonding process. Moreover, the two sides of the two wires 3a are respectively disposed on the positive and negative pole areas 21a, 22a. Hence, when the light source of the LED 2a is projected outwardly from the light-emitting surface 20a and through the phosphor resin body 4a, the two wires 3a would produce two shadow lines within the light emitted by the LED 2a and thus affect the LED's light-emitting efficiency.

### SUMMARY OF THE INVENTION

In view of the aforementioned issues, the present invention provides a semiconductor chip package structure for achieving electrical connection without using wire-bonding process and a method for making the same. Because the semiconductor chip package structure of the present invention can achieve electrical connection without using a wire-bonding process, the present invention can omit the wire-bonding process and avoid bad electrical connection in the semiconductor chip package structure.

To achieve the above-mentioned objectives, the present invention provides a semiconductor chip package structure for achieving electrical connection without using wire-bonding process, including: an insulative substrate unit, a package unit, at least one semiconductor chip, a first conductive unit, an insulative unit and a second conductive unit. The package unit has a package body and at least one through hole passing through the package body, and the package body is disposed on the insulative substrate unit to make the at least one through hole form at least one receiving groove. The at least one semiconductor chip is received in the at least one receiving groove. The semiconductor chip has a plurality of conductive pads disposed on a top surface thereof, and the conductive pads are insulated from each other by the package body. The first conductive unit has a plurality of first conductive layers formed on the package body, and one side of each first conductive layer is electrically connected to each conductive pad. The insulative unit has at least one insulative layer formed between the first conductive layers in order to insulate the first conductive layers from each other. The second conductive unit has a plurality of second conductive layers respectively formed on another sides of the first conductive layers.

To achieve the above-mentioned objectives, the present invention provides a method of making semiconductor chip package structures for achieving electrical connection without using wire-bonding process, including: arranging at least two semiconductor chips on an adhesive polymeric substance, wherein each semiconductor chip has a plurality of conductive pads disposed on its top surface and the conductive pads are exposed; covering the at least two semiconductor chips with a package unit; removing the adhesive polymeric substance in order to expose a bottom portion of each semiconductor chip and removing one part of the package unit in order to make the conductive pads exposed again; forming a plurality of first conductive layers on the package unit, wherein each first conductive layer is electrically connected to each conductive pad; forming a plurality of insulative layers between the first conducive layers in order to insulate the first conductive layers from each other; respectively forming a plurality of second conductive layers on the first conductive layers in order to respectively electrically connect the second conductive layers to the conductive pads; forming an insulative substrate unit on bottom sides of the at least two semiconductor chips; and forming at least two semiconductor chip package structures by a cutting process.

Therefore, the semiconductor chip package structure of the present invention can achieve electrical connection without using a wire-bonding process, so that the present invention can omit the wire-bonding process and avoid bad electrical connection in the semiconductor chip package structure.

In order to further understand the techniques, means and effects the present invention takes for achieving the prescribed objectives, the following detailed descriptions and appended drawings are hereby referred, such that, through which, the purposes, features and aspects of the present invention can be thoroughly and concretely appreciated; however, the appended drawings are merely provided for reference and illustration, without any intention to be used for limiting the present invention.

### BRIEF DESCRIPTION OF THE DRAWINGS

FIG. 1 is a side, schematic view of the LED package structure via a wire-bonding process according to the prior art;

FIG. 2 is a flowchart of the method of making semiconductor chip package structures for achieving electrical connection without using a wire-bonding process according to the present invention; and

FIGS. 2A to 2K are cross-sectional, schematic views of two semiconductor chip package structures for achieving electrical connection without using a wire-bonding process according to the present invention, at different stages of the packaging processes, respectively.

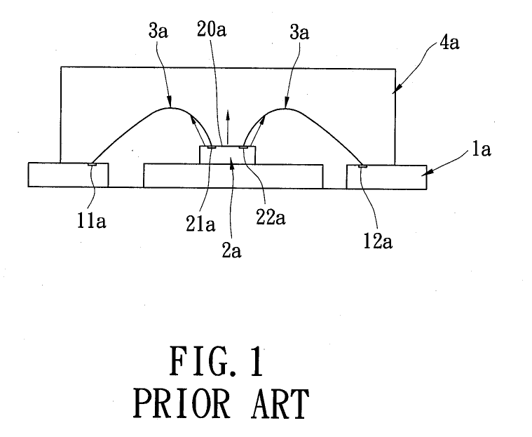

### DETAILED DESCRIPTION OF THE PREFERRED EMBODIMENTS

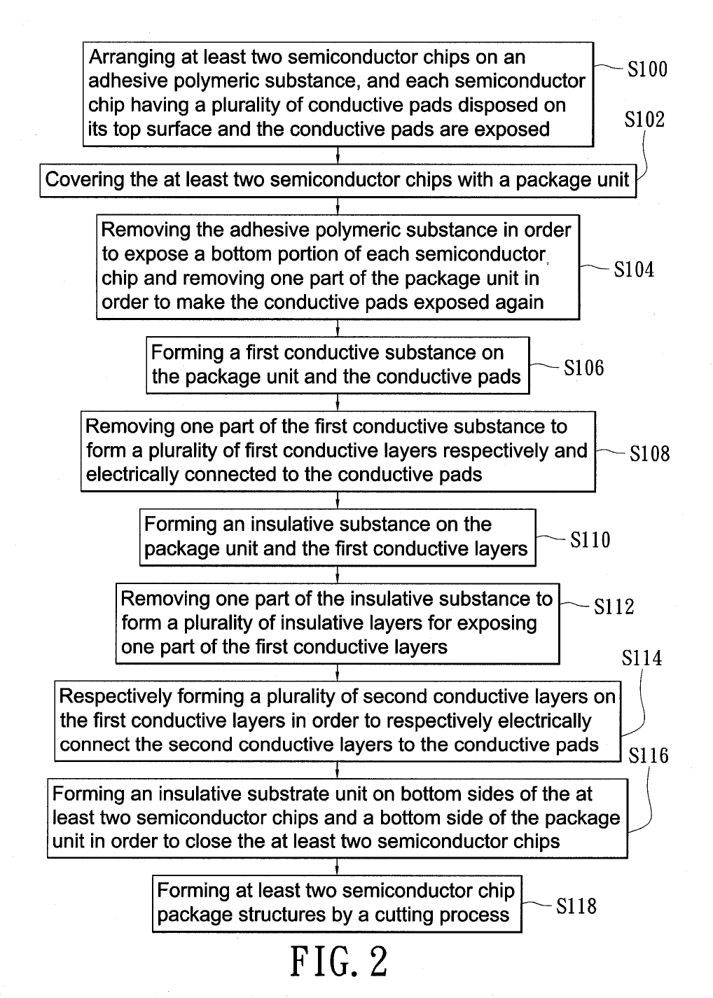

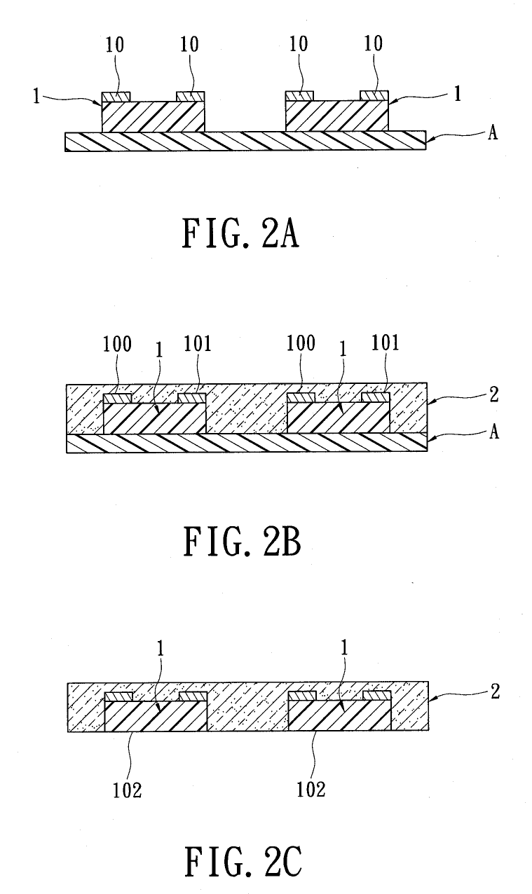

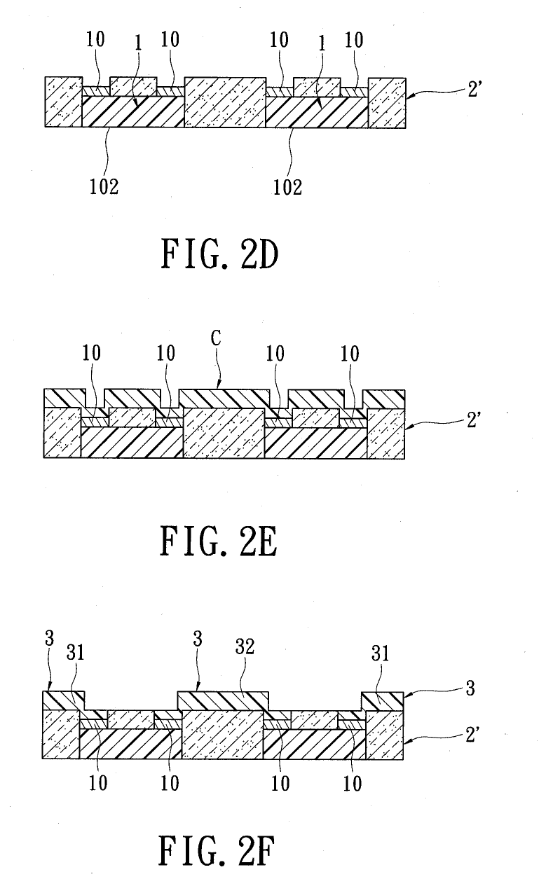

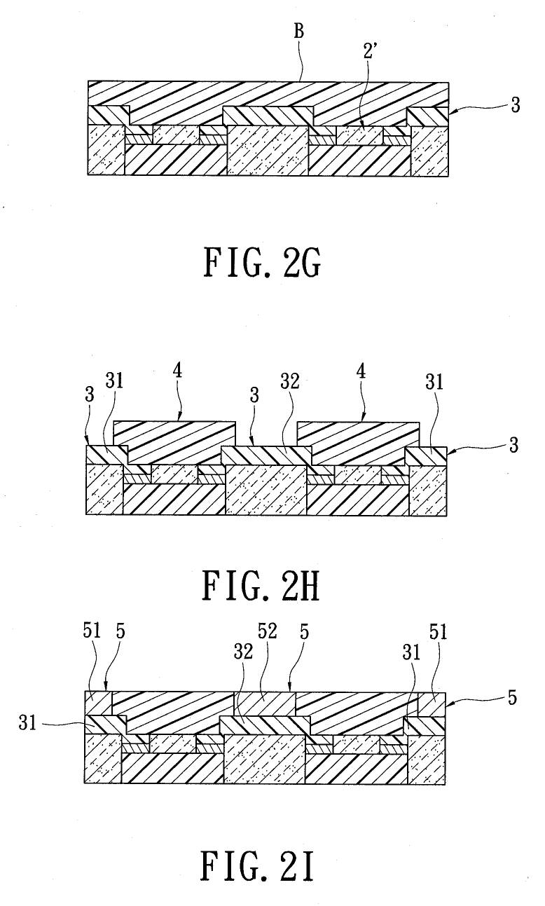

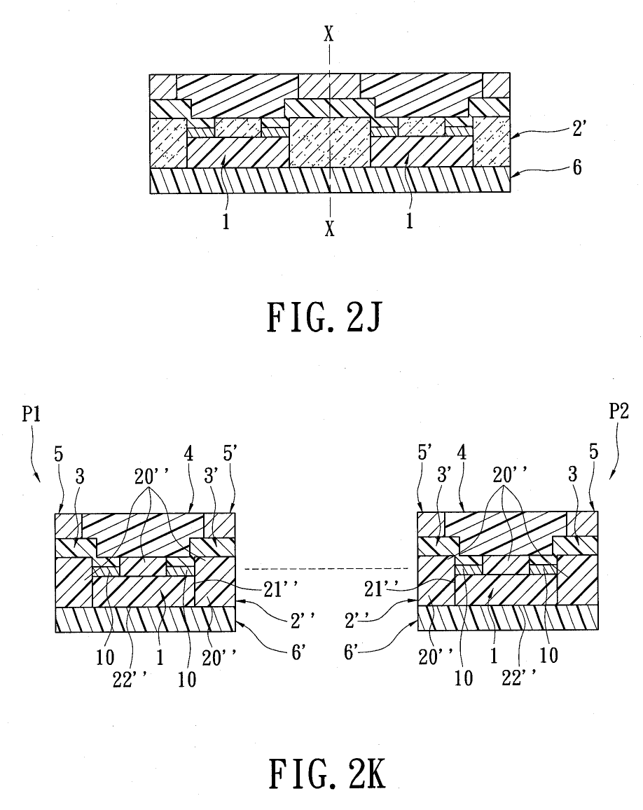

Referring to FIGS. 2 and 2A-2K, the present embodiment of the present invention provides a method of making semiconductor chip package structures for achieving electrical connection without using wire-bonding process, including as follows:

Step S100 is: referring to FIGS. 2 and 2A, arranging at least two semiconductor chips 1 on an adhesive polymeric substance A, and each semiconductor chip 1 having a plurality of conductive pads 10 disposed on its top surface and the conductive pads 10 are exposed. In addition, the adhesive polymeric substance A can be an adhesive removable substrate that is made of glass, ceramic, crystal material or plastic. In the present embodiment, each semiconductor chip 1 can be an LED (light emitted diode) chip.

Step S102 is: referring to FIGS. 2 and 2B, covering the at least two semiconductor chips 1 with a package unit 2. The at least two semiconductor chips 1 are covered with the package unit 2 by coating, spraying, printing or pressure molding. In the present embodiment, the package unit 2 can be a phosphor substance, and the conductive pads 10 of each semiconductor chip 1 are divided into a positive electrode pad 100 and a negative electrode pad 101.

Step S104 is: referring to FIGS. 2, 2C and 2D, removing the adhesive polymeric substance A in order to expose a bottom portion of each semiconductor chip 1 and removing one part of the package unit 2 (to form a package unit 2′) in order to make the conductive pads 10 exposed again. In addition, each semiconductor chips 1 has a light-emitting surface 102 on its bottom surface and opposite the conductive pads 10. In other words, the conductive pads 10 are disposed on one surface of each semiconductor chip 1, and the light-emitting surface 102 is formed on another opposite surface of each semiconductor chip 1. Of course, the step of S104 can be changed, for example: first, removing one part of the package unit 2 (to form a package unit 2′) in order to make the conductive pads 10 exposed again and then removing the adhesive polymeric substance A in order to expose a bottom portion of each semiconductor chip 1.

Step S106 is: referring to FIGS. 2 and 2E, forming a first conductive substance C on the package unit 2′ and the conductive pads 10. In addition, the first conductive substance C is formed on the package unit 2′ and the conductive pads 10 by evaporating, sputtering, electroplating or electroless plating.

Step S108 is: referring to FIGS. 2 and 2F, removing one part of the first conductive substance C to form a plurality of first conductive layers 3 respectively and electrically connected to the conductive pads 10. In other words, the one part of the first conductive substance C is removed by matching an exposure process, a development process and an etching process in order to make each first conductive layer 3 disposed on the package unit 2′ and electrically connected to each corresponding conductive pads 10. In addition, the first conductive layers 3 are divided into a plurality of first part conductive layers 31 and a plurality of second part conductive layers 32, one side of each first part conductive layer 31 is electrically connected to the corresponding conductive pad 10, and two opposite sides of each second part conducive layer 32 are electrically connected to the two corresponding conductive pads 10.

Step S110 is: referring to FIGS. 2 and 2G, forming an insulative substance B on the package unit 2′ and the first conductive layers 3. In addition, the insulative substance B is formed on the package unit 2′ and the first conductive layers 3 by printing, coasting or spraying, and the insulative substance B is hardened by pre-curing.

Step S112 is: referring to FIGS. 2 and 2H, removing one part of the insulative substance B to form a plurality of insulative layers 4 for exposing one part of the first conductive layers 3. In other words, the one part of the insulative substance B is removed by matching an exposure process, a development process and an etching process, and the insulative layers 4 are formed between the first conducive layers 3 in order to insulate the first conductive layers 3 from each other. In addition, each insulative layer 4 is formed between each first part conductive layer 31 and each second part conductive layer 32.

Step S114 is: referring to FIGS. 2 and 2I, respectively forming a plurality of second conductive layers 5 on the first conductive layers 3 in order to respectively electrically connect the second conductive layers 5 to the conductive pads 10. In addition, each second conductive layer 5 is formed on one exposed part of each first conductive layer 3 (it means one part of each first conductive layer 3 is exposed) by evaporating, sputtering, electroplating or electroless plating. In other words, one part of the second conductive layers 5 (external second conductive portions 51) is electrically connected to the opposite side of each first part conductive layer 31, and the other part of the second conductive layers 5 (central second conductive portion 52) is electrically disposed on a center position of each second part conductive layer 32.

Step S116 is: referring to FIGS. 2 and 2J, forming an insulative substrate unit 6 on bottom sides of the at least two semiconductor chips 1 and a bottom side of the package unit 2′ in order to close the at least two semiconductor chips 1. In addition, the bottom side of each semiconductor chip 1 and the bottom side of the package unit 2′ are covered with the insulative substrate unit 6 by coating, spraying, printing or pressure molding.

Step S118 is: referring to FIGS. 2 and 2K, forming at least two semiconductor chip package structures (P1, P2) by a cutting process along the dotted line X of the FIG. 2J.

Therefore, each semiconductor chip package structure (P1, P2) includes a semiconductor chip 1, a package unit 2″, a first conductive unit, a second conductive unit and an insulative substrate unit 6′.

The package unit 2″ has a package body 20″ and at least one through hole 21″ passing through the package body 20″. The package body 20″ is disposed on the insulative substrate unit 6′ to make the at least one through hole 21″ form at least one receiving groove 22″. The at least one semiconductor chip 1 is received in the at least one receiving groove 22″. The semiconductor chip 1 has a plurality of conductive pads 10 disposed on a top surface thereof, and the conductive pads 10 are insulated from each other by one part of the package body 20″. The first conductive unit has a plurality of first conductive layers (3, 3′) formed on the package body 20″, and one side of each first conductive layer (3 or 3′) is electrically connected to each corresponding conductive pad 10. The insulative unit has at least one insulative layer 4 formed between the first conductive layers (3, 3′) in order to insulate the first conductive layers (3, 3′) from each other. The second conductive unit has a plurality of second conductive layers (5, 5′) respectively formed on another sides of the first conductive layers (3, 3′). In addition, the insulative unit has an insulative layer 4 formed on the package body 20″ and the first conductive layers (3, 3′) and between the second conductive layers (5, 5′).

Furthermore, there are some different choices of the semiconductor chips 1, the package unit 2″ and the insulative substrate unit 6′ in the present embodiment, as follows:

1. Each semiconductor chip 1 can be an LED (light-emitting diode) chip, and the insulative substrate unit 6′ and the package unit 2″ can be phosphor substances. The conductive pads 10 of each semiconductor chip 1 are divided into a positive electrode pad 100 and a negative electrode pad 101. For example, the LED chip is a blue LED chip. Therefore, the present invention can generate white light by matching the blue LED chip and the phosphor substances.

2. Each semiconductor chip 1 can be an LED chip, the insulative substrate unit 6′ can be a phosphor substance, and the package unit 2″ can be an opaque substance. Hence, the white light generated by the present invention can be condensed by using the package unit 2″, and the white light only passes through the insulative substrate unit 6′.

3. Each semiconductor chip 1 can be an LED (light-emitting diode) chip, and the insulative substrate unit 6′ and the package unit 2″ can be transparent substances. The conductive pads 10 of each semiconductor chip 1 are divided into a positive electrode pad 100 and a negative electrode pad 101. For example, the LED chip is a red LED chip. Therefore, the present invention can generate red light by matching the red LED chip and the transparent substances.

4. Each semiconductor chip 1 can be an LED chip, and the insulative substrate unit 6′ can be a transparent substance, the package unit 2″ can be an opaque substance. Hence, light generated by the present invention can be condensed by using the package unit 2″, and the light only passes through the insulative substrate unit 6′.

5. Each semiconductor chip 1 can be a light-sensing chip, the insulative substrate unit 6′ and the package unit 2″ can be transparent substances or translucent substances, and the conductive pads 10 are divided into an electrode pad set and a signal pad set.

6. Each semiconductor chip 1 can be a light-sensing chip, the insulative substrate unit 6′ can be a transparent substance or a translucent substance, the package unit 2″ can be an opaque substance, and the conductive pads 10 are divided into an electrode pad set and a signal pad set.

7. Each semiconductor chip 1 can be an IC (Integrated Circuit) chip, the insulative substrate unit 6′ and the package unit 2″ can be opaque substances, and the conductive pads 10 are divided into an electrode pad set and a signal pad set.

Therefore, the semiconductor chip package structure of the present invention can achieve electrical connection without using a wire-bonding process, so that the present invention can omit the wire-bonding process and avoid bad electrical connection in the semiconductor chip package structure.

The above-mentioned descriptions represent merely the preferred embodiment of the present invention, without any intention to limit the scope of the present invention thereto. Various equivalent changes, alternations or modifications based on the claims of present invention are all consequently viewed as being embraced by the scope of the present invention.

What is claimed is:

1. A semiconductor chip package structure for achieving electrical connection without using wire-bonding process, comprising:
an insulative substrate unit;
a package unit having a package body and at least one through hole passing through the package body, wherein the package body is disposed on the insulative substrate unit to make the at least one through hole form at least one receiving groove;
at least one semiconductor chip received in the at least one receiving groove, wherein the semiconductor chip has a plurality of conductive pads disposed on a top surface thereof, and the conductive pads are insulated from each other by the package body;
a first conductive unit having a plurality of first conductive layers formed on the package body, wherein one side of each first conductive layer is electrically connected to each conductive pad;
an insulative unit having at least one insulative layer formed between the first conductive layers in order to insulate the first conductive layers from each other; and
a second conductive unit having a plurality of second conductive layers respectively formed on another sides of the first conductive layers.

2. The semiconductor chip package structure as claimed in claim 1, wherein the at least one semiconductor chip is an LED chip, the insulative substrate unit and the package unit are phosphor substances or transparent substances, the conductive pads are divided into a positive electrode pad and a negative electrode pad, and the semiconductor chip has a light-emitting surface on its bottom surface and opposite the conductive pads.

3. The semiconductor chip package structure as claimed in claim 1, wherein the at least one semiconductor chip is an LED chip, the insulative substrate unit is a phosphor substance or a transparent substance, the package unit is an opaque substance, the conductive pads are divided into a positive electrode pad and a negative electrode pad, and the semiconductor chip has a light-emitting surface on its bottom surface and opposite the conductive pads.

4. The semiconductor chip package structure as claimed in claim 1, wherein the at least one semiconductor chip is a light-sensing chip, the insulative substrate unit and the package unit are transparent substances or translucent substances, and the conductive pads are divided into an electrode pad set and a signal pad set.

5. The semiconductor chip package structure as claimed in claim 1, wherein the at least one semiconductor chip is a light-sensing chip, the insulative substrate unit is a transparent substance or a translucent substance, the package unit is an opaque substance, and the conductive pads are divided into an electrode pad set and a signal pad set.

6. The semiconductor chip package structure as claimed in claim 1, wherein the at least one semiconductor chip is an IC (Integrated Circuit) chip, the insulative substrate unit and the package unit are opaque substances, and the conductive pads are divided into an electrode pad set and a signal pad set.

7. The semiconductor chip package structure as claimed in claim 1, wherein the insulative unit is formed on the package body and the first conductive layers and between the second conductive layers.

8. A method of making semiconductor chip package structures for achieving electrical connection without using wire-bonding process, comprising:
arranging at least two semiconductor chips on an adhesive polymeric substance, wherein each semiconductor chip has a plurality of conductive pads disposed on its top surface and the conductive pads are exposed;
covering the at least two semiconductor chips with a package unit;
removing the adhesive polymeric substance in order to expose a bottom portion of each semiconductor chip and removing one part of the package unit in order to make the conductive pads exposed again;
forming a plurality of first conductive layers on the package unit, wherein each first conductive layer is electrically connected to each conductive pad;
forming a plurality of insulative layers between the first conducive layers in order to insulate the first conductive layers from each other;
respectively forming a plurality of second conductive layers on the first conductive layers in order to respectively electrically connect the second conductive layers to the conductive pads;
forming an insulative substrate unit on bottom sides of the at least two semiconductor chips; and
forming at least two semiconductor chip package structures by a cutting process.

9. The method as claimed in claim 8, wherein the adhesive polymeric substance is an adhesive removable substrate that is made of glass, ceramic, crystal material or plastic.

10. The method as claimed in claim 8, wherein the at least one semiconductor chip is an LED chip, the insulative substrate unit and the package unit are phosphor substances or transparent substances, the conductive pads are divided into a positive electrode pad and a negative electrode pad, and the semiconductor chip has a light-emitting surface on its bottom surface and opposite the conductive pads.

11. The method as claimed in claim 8, wherein the at least one semiconductor chip is an LED chip, the insulative substrate unit is a phosphor substance or a transparent substance, the package unit is an opaque substance, the conductive pads are divided into a positive electrode pad and a negative electrode pad, and the semiconductor chip has a light-emitting surface on its bottom surface and opposite the conductive pads.

12. The method as claimed in claim 8, wherein the at least one semiconductor chip is a light-sensing chip, the insulative substrate unit and the package unit are transparent substances or translucent substances, and the conductive pads are divided into an electrode pad set and a signal pad set.

13. The method as claimed in claim 8, wherein the at least one semiconductor chip is a light-sensing chip, the insulative substrate unit is a transparent substance or a translucent substance, the package unit is an opaque substance, and the conductive pads are divided into an electrode pad set and a signal pad set.

14. The method as claimed in claim 8, wherein the at least one semiconductor chip is an IC (Integrated Circuit) chip, the insulative substrate unit and the package unit are opaque substances, and the conductive pads are divided into an electrode pad set and a signal pad set.

15. The method as claimed in claim 8, wherein the at least two semiconductor chips are covered with the package unit by coating, spraying, printing or pressure molding.

16. The method as claimed in claim 8, wherein the step of forming the first conductive layers further comprises:
forming a first conductive substance on the package unit and the conductive pads; and
removing one part of the first conductive substance to form the first conductive layers respectively and electrically connected to the conductive pads;
wherein the first conductive substance is formed on the package unit and the conductive pads by evaporating, sputtering, electroplating or electroless plating, and the one part of the first conductive substance is removed by matching an exposure process, a development process and an etching process.

17. The method as claimed in claim 8, wherein the step of forming the insulative layers further comprises:
forming an insulative substance on the package unit and the first conductive layers; and
removing one part of the insulative substance to form the insulative layers for exposing one part of the first conductive layers;
wherein the insulative substance is formed on the package unit and the first conductive layers by printing, coasting or spraying, and the insulative substance is hardened by pre-curing and the one part of the insulative substance is removed by matching an exposure process, a development process and an etching process.

18. The method as claimed in claim 17, wherein each second conductive layer is formed on one exposed part of each first conductive layer by evaporating, sputtering, electroplating or electroless plating.

19. The method as claimed in claim 8, wherein the first conductive layers are divided into a plurality of first part conductive layers and a plurality of second part conductive layers, one side of each first part conductive layer is electrically connected to the corresponding conductive pad, two opposite sides of each second part conducive layer are electrically connected to the two corresponding conductive pads, each insulative layer is formed between each first part conductive layer and each second part conductive layer, one part of the second conductive layers is electrically connected to the opposite side of each first part conductive layer, and the other part of the second conductive layers is electrically disposed on a center position of each second part conductive layer.

20. The method as claimed in claim 8, wherein the insulative substrate unit is formed on a bottom side of the package unit in order to close the at least two semiconductor chips.

21. The method as claimed in claim 20, wherein the bottom side of each semiconductor chip and the bottom side of the package unit are covered with the insulative substrate unit by coating, spraying, printing or pressure molding.
